(19) United States
(12) Patent Application Publication
(10) Pub. No.: US 2006/0223296 A1
(43) Pub. Date: Oct. 5, 2006

(54) Semiconductor device having self-aligned silicide layer and method thereof

(76) Inventors: Min-Chul Sun, Suwon-si (KR); Ja-Hum Ku, Seongnam-si (KR); Sug-Woo Jung, Suwon-si (KR); Sung-Kee Han, Seongnam-si (KR); Min-Joo Kim, Anyang-si (KR); Kwan-Jong Roh, Gunpo-si (KR)

Correspondence Address: MILLS & ONELLO LLP, ELEVEN BEACON STREET, SUITE 605, BOSTON, MA, 02108, US

(21) Appl. No.: 11/180,885

(22) Filed: Jul. 13, 2005

(30) Foreign Application Priority Data
Jul. 14, 2004 (KR) 10-2004-0054860

(51) Int. Cl. H01L 21/3205; H01L 21/44; H01L 21/4763

(52) U.S. Cl. 438/595; 438/655

(57) ABSTRACT

A semiconductor device having a self-aligned silicide layer and a method thereof are provided. The device includes a device isolation layer formed on the substrate to define an active region and a gate pattern crossing over the active region. A spacer insulating layer is formed on both sidewalls of the gate pattern. First and second salicide layers are formed on an upper portion of the gate pattern, and the first salicide layer is formed on the active region between the spacer insulating layer and the device isolation layer. The first and the second salicide layers on the gate pattern are alternately formed to be connected with each other. The first salicide layer is agglomeratedly formed on a narrow gate pattern, and the second salicide layer is formed within interrupted portions of the first salicide layer, thereby forming a patched salicide layer.

### CROSS-REFERENCE TO RELATED APPLICATIONS

This U.S. non-provisional patent application claims priority under 35 U.S.C. § 119 of Korean Patent Application 2004-54860 filed on Jul. 14, 2004, the entire contents of which are hereby incorporated by reference.

### BACKGROUND OF THE INVENTION

The present invention relates to semiconductor devices and methods for forming the same, and more particularly, to a semiconductor device having a self-aligned silicide layer on a semiconductor layer, that is, a salicide layer, and a method thereof.

Semiconductor devices of high access speed and high performance require low resistance source/drains and gate electrodes. In general, a low resistance metal silicide layer is formed on the source/drains and the gate electrodes so that they have a low resistance.

FIG. 1 is a process flow chart illustrating a conventional silicidation process.

Referring to FIG. 1, in a general self-aligned silicidation process, a metal is diffused into an exposed semiconductor layer to form self-aligned silicide layers, namely salicide layers. As the self-aligned silicidation process has an advantage that a silicide layer is formed at an isolated region, it is usually used for forming a silicide layer on gate electrodes and source/drains.

Referring to FIG. 1, the conventional silicidation process includes: forming a metal layer on a semiconductor layer S1; and annealing the semiconductor layer on which the metal layer is formed at a high temperature to form a silicide layer S2. During the annealing at high temperature, metal atoms of a metal layer are diffused into a semiconductor layer and bonded to semiconductor atoms to form a metal silicide layer. A remaining metal layer which was not diffused into the semiconductor layer is removed with a wet cleaning S3.

In general, cobalt and nickel used for forming silicide have different aspects in their forming process and shape. If cobalt silicide is formed at a high temperature, it has a low resistance. If the semiconductor layer has a narrow exposure, the silicide layer is agglomerated at a high temperature. Accordingly, the low resistance cobalt silicide layer formed at a high temperature is agglomeratedly formed on an upper portion of a gate pattern with a small linewidth to be partially cut.

As shown in FIGS. 2A and 2B, a salicide layer is formed on an upper portion of the gate pattern 14 formed on the substrate 10 and also on the substrate 10 exposed on both sides of the gate pattern 14. The device isolation layer 12 formed on the substrate 10 defines an active region, and the gate pattern 14 is formed on the active region. A spacer insulating layer 16 is formed on both sidewalls of the gate pattern 14, a source/drain salicide layer 18s is formed on the substrate between the spacer insulating layer 16 and the device isolation layer 12, and a gate salicide layer 18s′ is formed on an upper portion of the gate pattern 14. The cobalt silicide layer, as shown in FIG. 2A, has a good interfacial morphology with a semiconductor layer, but the gate salicide layer 18s′, as shown in FIG. 2B, is agglomeratedly formed on an upper portion of the gate pattern 14 with a small linewidth to be partially cut. The cobalt siliclide is agglomerated greatly if a linewidth of a gate becomes less than 5 nm.

Unlike a cobalt silicide layer, a nickel silicide layer has a low resistance if it is formed at a low temperature. Accordingly, a silicide layer may be formed before the silicide layer is agglomerated. However, if the silicide layer is not uniformly diffused into the semiconductor layer and formed on source/drains, electric fields are concentrated at a nonuniform interface and a leakage current is generated. As shown in FIGS. 3A and 3B, a nickel silicide layer has an extremely poor interfacial morphology with a semiconductor layer like a cobalt silicide layer. As shown in FIG. 2A, a source/drain salicide layer 22s is diffused into the substrate, to degrade its morphology, thereby increasing a source/drain junction leakage. However, as the low resistance nickel silicide layer is formed at a lower temperature than the cobalt silicide layer, a gate salicide layer 22s′ is not agglomerated on an upper portion of the gate pattern 14 with a small linewidth.

### SUMMARY OF THE INVENTION

It is therefore a feature of the invention to provide a semiconductor device and a method of manufacturing the device, in which the self-aligned silicide layer is not agglomerated and a junction leakage is restrained.

In accordance with a first aspect, the present invention is directed to a semiconductor device having a patched salicide layer. The device includes a device isolation layer formed on a substrate to define an active region and a gate pattern crossing over the active region. A spacer insulating layer is formed on sidewalls of the gate pattern. A first salicide layer is formed on an upper portion of the gate pattern and on the active region between the spacer insulating layer and the device isolation layer. A second salicide layer is formed on the upper portion of the gate pattern. The first and the second salicide layers are formed to be connected to each other on the upper portion of the gate pattern.

In one embodiment, the first salicide layer is agglomeratedly formed on the upper portion of the gate pattern, and the second salicide layer is formed between interrupted portions of the agglomerated first salicide layer. The first salicide layer may include a metal element reacted to be low resistance silcide at a high temperature ranging from 650° C. to 850° C. For example, the first salicide layer may include cobalt. The second salicide layer may include a metal element reacted to be low resistance silicide at a low temperature ranging from 300° C. to 550° C., for example, nickel.

In accordance with another aspect, the present invention is also directed to a method for fabricating a semiconductor device including a salicide patch. The method includes forming a device isolation layer on a semiconductor substrate to define an active region, forming a gate pattern crossing over the active region, and forming a spacer insulating layer on sidewalls of the gate pattern. A partially interrupted or cut first salicide layer is formed on an upper portion of the gate pattern while the first salicide layer is formed at the active region between the spacer insulating layer and the device isolation layer, by performing a first silicidation process. A second salicide layer is formed on an upper portion of a gate pattern to electrically connect disconnected portions of the interrupted first salicide layer, such that the second salicide layer is connected to the first salicide layer.

In one embodiment, the first salicide layer is agglomeratedly formed on an upper portion of the gate pattern, and the second salicide layer is formed to patch between interrupted portions of the first salicide layer. The first salicide layer may be formed by performing silicide annealing at a high temperature ranging from 650° C. to 850° C., and the second salicide layer may be formed by performing silicide annealing at a low temperature ranging from 300° C. to 550° C. The first salicide layer may be formed of a metal reacted to be low resistance silicide at a high temperature, and the second salicide layer may be formed of a metal reacted to be low resistance silicide at a low temperature.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity. FIG. 1 is a process flow chart illustrating a conventional silicidation process.

FIGS. 2A, 2B, 3A and 3B are cross-sectional views and plan views illustrating a silicide layer in accordance with conventional art, respectively.

FIG. 4 is a process flow chart illustrating a silicidation process in accordance with a preferred embodiment of the present invention.

FIGS. 5A, 6A, 7A, 8A, 9A and 10A are schematic plan views illustrating a method for fabricating a semiconductor device in accordance with a preferred embodiment of the present invention.

FIGS. 5B, 6B, 7B, 8B, 9B and 10B are schematic cross-sectional views taken along a line I-I′ of FIGS. 5A, 6A, 7A, 8A, 9A and 10A, respectively.

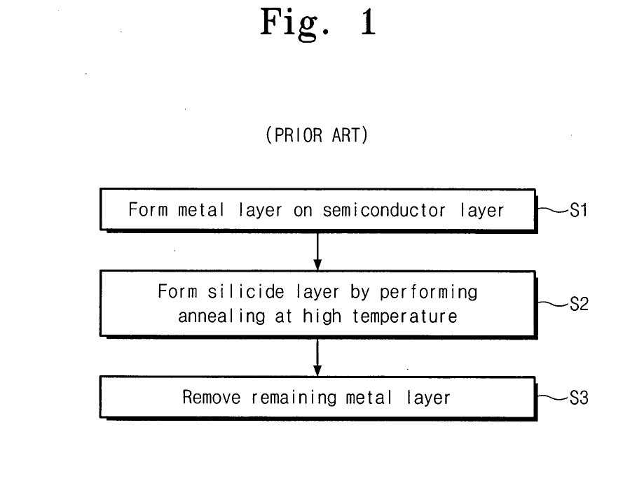

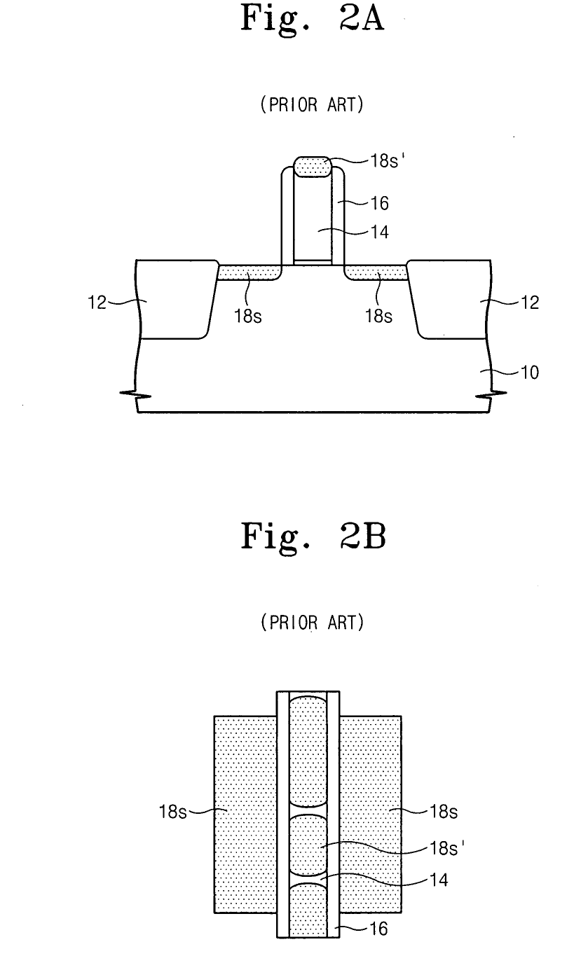

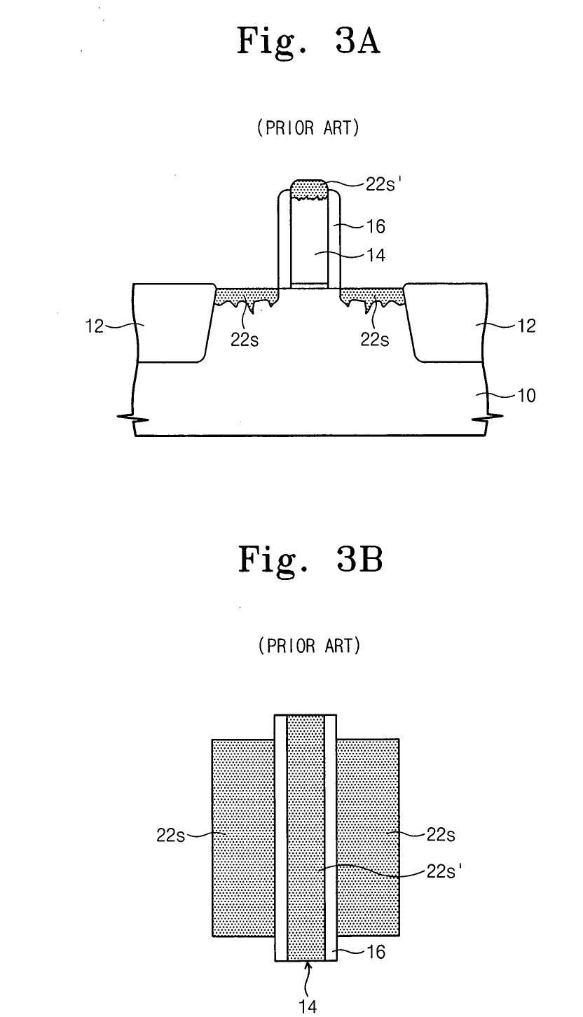

### DETAILED DESCRIPTION OF PREFERRED EMBODIMENTS

Preferred embodiments of the present invention will be described below in more detail with reference to the accompanying drawings. It will be understood that when a layer is referred to as being “on” another layer or substrate, it can be directly on the other layer or substrate, or intervening layers may also be present.

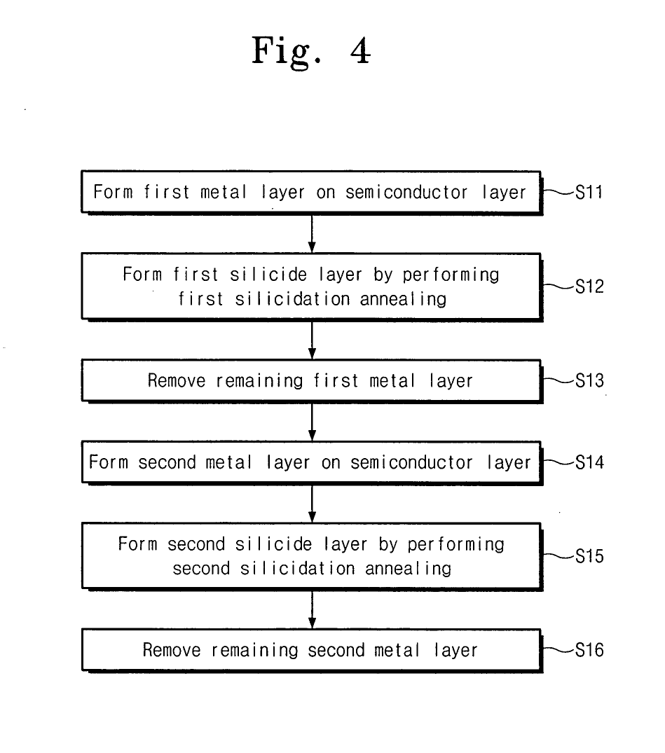

FIG. 4 is a process flow chart illustrating a silicidation process in accordance with a preferred embodiment of the present invention.

Referring to FIG. 4, a first metal layer is formed on a semiconductor layer S11, and a first silicide layer is formed by a first silicidation annealing S12. The semiconductor layer may be a mono-crystalline substrate, an epitaxial layer, an amorphous or a poly-crystalline layer.

A remaining portion of the first metal layer which was not silicidized is removed S13. The first metal layer includes elements with a good interfacial morphology between a silicide layer and a semiconductor layer, even though a silicide layer may be agglomerated. For example, the first metal layer may be a cobalt layer forming low resistance silicide at a temperature ranging from 650° C. to 850° C. and having a good interfacial morphology between a semiconductor layer and a silicide layer.

A second metal layer is formed on the semiconductor layer on which a first silicide layer is formed S14 by performing a second silicidation annealing S15. A remaining portion of the second metal layer which was not silicidized is removed S16, after the second silicide layer is formed. The second metal layer includes atoms of which a silicide layer is not agglomerated even though it has a bad interfacial morphology between a silicide layer and a semiconductor layer. For example, the second metal layer may be a nickel layer forming low resistance silicide at a temperature ranging from 300° C. to 550° C. and of which a silicide layer is not agglomerated.

The second silicide layer performs a function to patch the first silicide layers agglomeratedly formed to be partially cut. It is desirable that the second silicidation annealing is performed at a temperature where a metal atom of a second metal layer penetrates the first silicide later not to be diffused into a semiconductor layer.

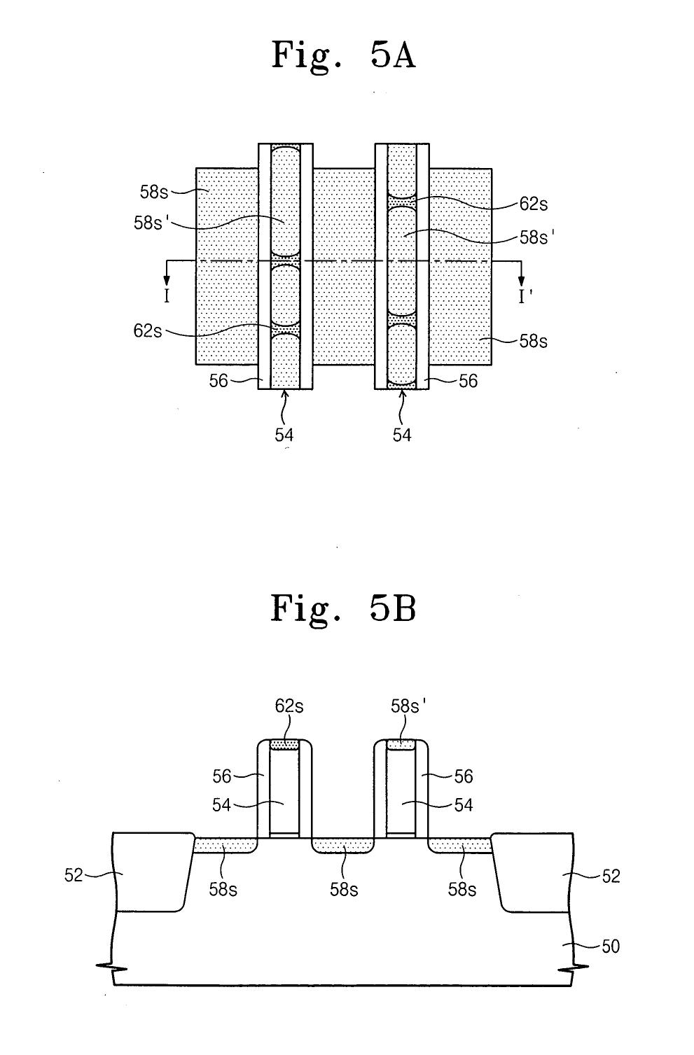

FIG. 5A is a plan view illustrating a semiconductor device in accordance with a preferred embodiment of the present invention.

FIG. 5B is a cross-sectional view taken along a line I-I′ of FIG. 5A.

Referring to FIGS. 5A and 5B, a device isolation layer 52 defining an active region is formed on a substrate 50, and a gate pattern 54 is formed on the active region. A spacer insulating layer 56 is formed on both sidewalls of the gate pattern 54. A source/drain salicide layer 58s is formed on a substrate exposed between the spacer insulating layer 56 and the device isolation layer 52, and a gate salicide layer consisting of a first gate salicide layer 58s′ and a second gate salicide layer 62s is formed on a gate pattern 54 exposed between the spacer insulating layers 56. The first gate salicide layer 58s′ is agglomeratedly formed such that gaps are formed between portions of the first gate silicide layer 58s′, that is, the first gate silicide layer 58s′ is formed to be partially cut, and the second gate salicide layer 62s is formed between the separated portions of the first gate salicide layer 58s′ to be connected with the partially cut first gate salicide layer 58s′. The first gate salicide layer 58s′ and the source/drain salicide layer 58s are formed of a first silicide containing a first metal element, and the second gate salicide layer 62s is formed of second silicide containing a second metal element. The first and second silicide may include one or plurality of elements selected from a group consisting of tantalum, zirconium, titanium, hafnium, tungsten, cobalt, nickel, platinum, lead, vanadium and niobium.

Preferably, the first silicide includes metal atoms reacted to be low resistance silicide at a temperature ranging from 650° C. to 850° C., and the second silicide includes metal atoms reacted to be low resistance silicide at a temperature ranging from 300° C. to 550° C. For example, the first silicide may include cobalt, and the second silicide may include nickel. As the first silicide is formed at a high temperature, it is uniformly formed on the source/drain regions with a large width, but it is formed on the gate pattern with a small width to be partially cut because an agglomeration phenomenon occurs. In contrast, as the second silicide is formed at a low temperature, even if it is formed on a gate pattern with a small linewidth, an agglomeration phenomenon does not occur. Accordingly, the second silicide is patched between the agglomerated portions of the first silicide to form a continuous gate salicide layer. The second silicide may have a poor interfacial morphology with a semiconductor layer. Accordingly, if the second silicide is formed on source/drain regions, a junction leakage may be increased. According to the present invention, as the second silicide is formed only on the gate pattern not on the source/drain regions, it is possible to patch partial cuts of the gate salicide layer without increasing source/drain junction leakage.

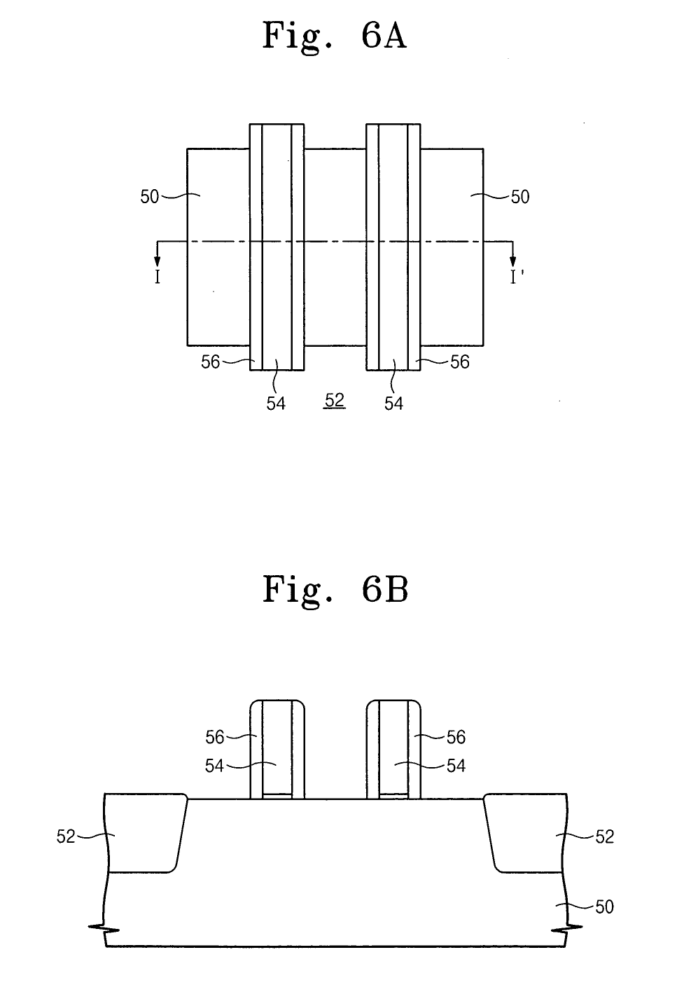

FIGS. 6A, 7A, 8A, 9A and 10A are plan views illustrating a method for fabricating a semiconductor device in accordance with a preferred embodiment of the present invention.

FIGS. 6B, 7B, 8B, 9B and 10B are cross-sectional views taken along a line I-I′ of FIGS. 5A, 6A, 7A, 8A, 9A and 10A, respectively.

Referring to FIGS. 6A and 6B, a device isolation layer 52 is formed on the substrate 50 to define an active region. A gate pattern 54 is formed on the active region, and a spacer insulating layer 56 is formed on both sidewalls of the gate pattern 54.

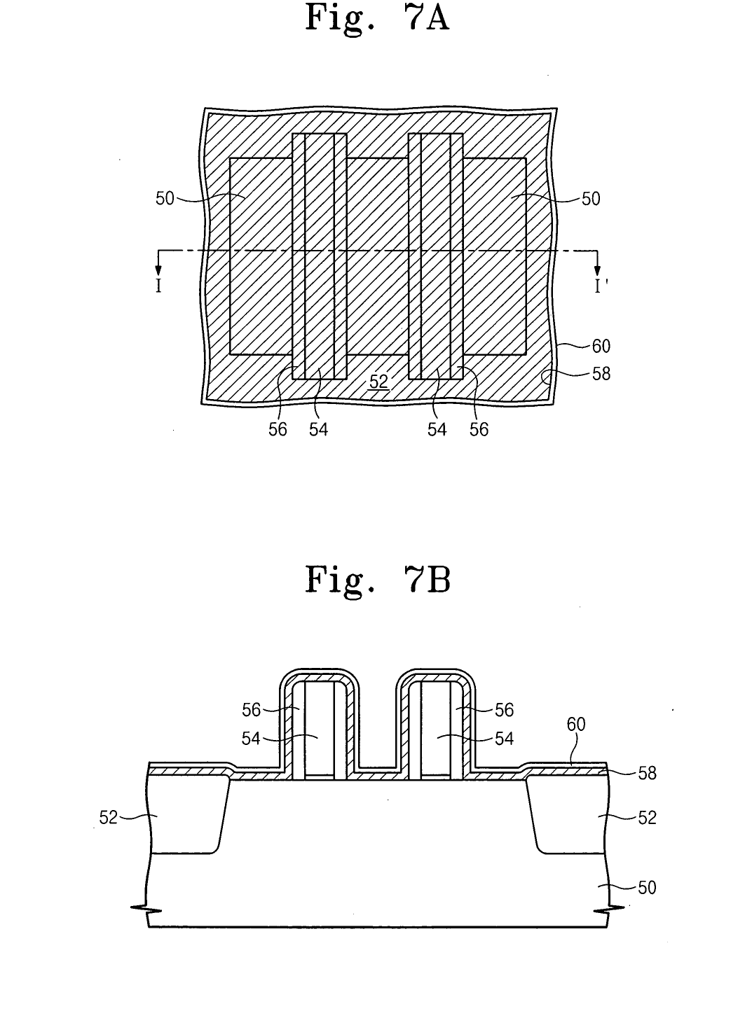

Referring to FIGS. 7A and 7B, a first metal layer 58 is formed on a surface of the substrate 50, and a first capping layer 60 is formed on the first metal layer 58 to prevent the first metal layer 58 from being oxidized and to improve a morphology of a silicide layer. The first metal layer 58 may be formed of a single layer or a stacked layer being a metal layer including one or plurality of elements selected from a group consisting of tantalum, zirconium, titanium, hafnium, tungsten, cobalt, nickel, platinum, lead, vanadium and niobium.

It is preferable that the first metal layer 58 be formed of a metal reacted to be low resistance silicide at a temperature ranging from 650° C. to 850° C. For example, the first metal layer 58 may be formed of cobalt.

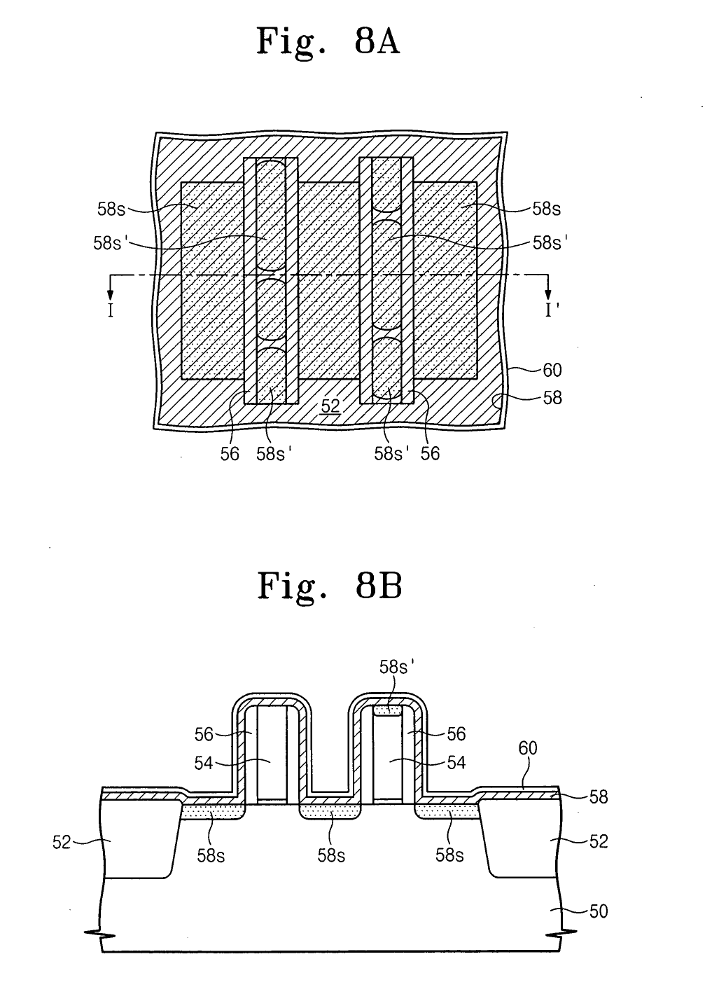

Referring to FIGS. 8A and 8B, a first silicidation annealing is performed to form a first salicide layer on the gate pattern 54 exposed between the spacer insulating layers 56 and on portions of the substrate 50 exposed between the spacer insulating layer 56 and the device insulating layer 52. A first gate salicide layer 58s′ is formed on the gate pattern, and a source/drain salicide layer 58s is formed on the substrate. As the first silicidation annealing is performed at a high temperature ranging from 650° C. to 850° C., the first salicide layer may be agglomerated. As shown in FIG. 8B, a uniform silicide layer is formed on the substrate with a large exposed width, but a silicide layer is agglomeratedly formed on a gate pattern 54 with a small exposed width that is partially interrupted or cut.

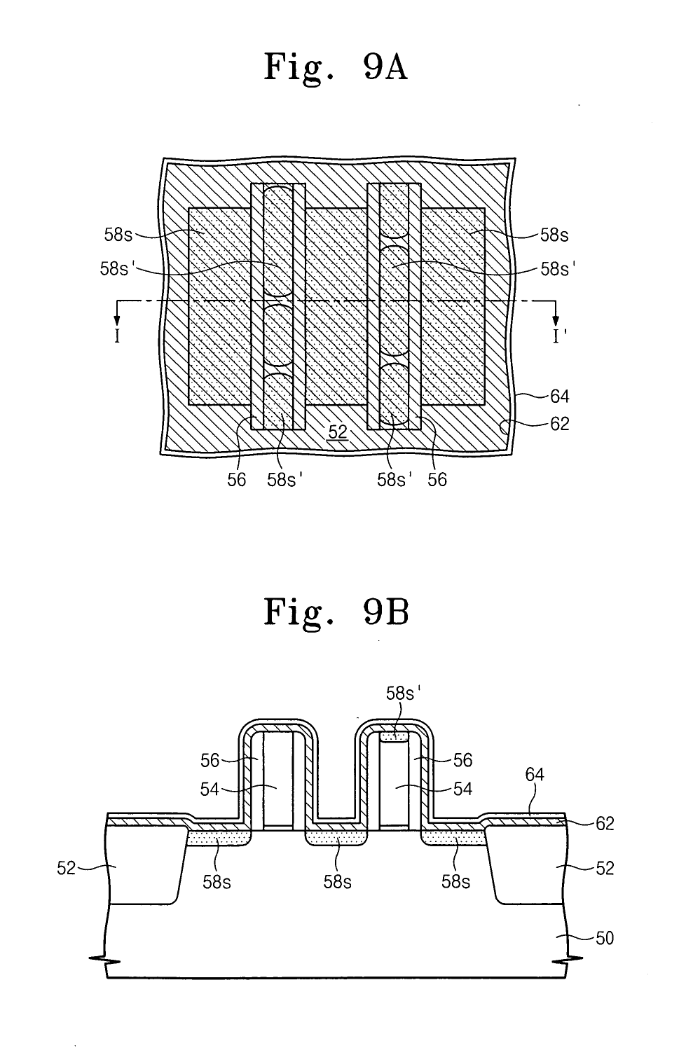

Referring to FIGS. 9A and 9B, the first capping layer 60 is removed, and the remaining portion of the first metal layer 58 that was not silicidized is removed. A second metal layer 62 and a second capping layer 64 are formed on a surface of a substrate from which the first metal layer 58 is removed. The second capping layer 64 also plays a role in preventing a metal layer from being oxidized and improving a morphology of a silicide layer.

The second metal layer 62 may be formed of a single layer or a stacked layer being a metal layer including one or a plurality of elements selected from a group consisting of tantalum, zirconium, titanium, hafnium, tungsten, platinum, lead, vanadium and niobium. Preferably, the second metal layer 62 is formed of a metal reacted to be a low resistance silicide layer at a temperature ranging from 300° C. to 550° C. For example, the second metal layer 62 may be formed of nickel.

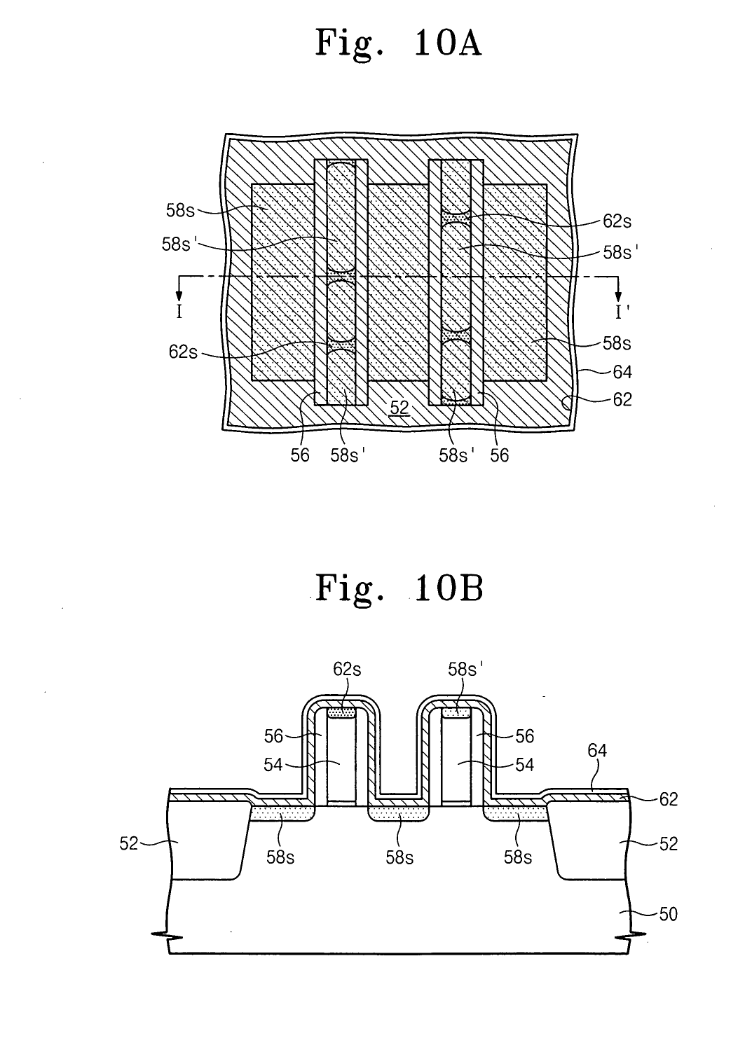

Referring to FIGS. 10A and 10B, a second silicidation annealing is performed to form a second salicide layer 62s on a gate pattern on which the first gate salicide layer 58s′ is not formed. If the second salicidation annealing is performed at a high temperature, a resistance of a silicide layer may be increased, and a second metal atom penetrates the first silicide layer to be diffused into the substrate 50. Accordingly, it is preferable that the second silicidation annealing be performed at a temperature ranging from 300° C. to 550° C.

A second gate salicide layer 62s is formed where the first gate salicide layer 58s′ is interrupted, that is, where the first gate salicide layer 58s′ is not formed, by performing the second silicidation annealing. The first metal element is not diffused into the substrate. ccordingly, a gate salicide layer connecting a first gate salicide layer 58s′ and the second gate salicide layer 62s is formed on the gate pattern 54, and a source/drain salicide layer 58s consisting of a first silicide layer is formed on the substrate 50.

It should be noted that the resulting structure shown in FIGS. 5A and 5B can be obtained even though the second capping layer 64 and the second metal layer 62 are removed.

According to the present invention described as above, even if a silicide layer is agglomeratedly formed at a narrow region to be partially interrupted, it is possible to form a first silicide layer having a good interfacial morphology with a semiconductor substrate, a continuous salicide layer on a gate pattern by patching the interrupted portions with the second silicide layer and a salicide layer at socurce/drain regions not to increase a junction leakage.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a device isolation layer formed on a substrate to define an active region;
a gate pattern crossing over the active region;
a spacer insulating layer formed on both sidewalls of the gate pattern;
a first salicide layer formed on an upper portion of the gate pattern and on the active region between the spacer insulating layer and the device isolation layer; and
a second salicide layer formed on the upper portion of the gate pattern,
wherein the first and the second salicide layers are formed to be connected each other on the upper portion of the gate pattern.

2. The device of claim 1, wherein the first salicide layer is agglomeratedly formed on the upper portion of the gate pattern, and the second salicide layer is formed between interrupted portions of the agglomerated first salicide layer.

3. The device of claim 1, wherein the first salicide layer includes a metal reacted to be low resistance silicide at a high temperature ranging from 650° C. to 850° C.

4. The device of claim 3, wherein the first salicide layer includes cobalt.

5. The device of claim 1, wherein the second salicide layer includes a metal reacted to be low resistance silicide at a low temperature ranging from 300° C. to 550° C.

6. The device of claim 5, wherein the second salicide layer includes nickel.

7. A method for fabricating a semiconductor device comprising:
forming a device isolation layer on a semiconductor substrate to define an active region;
forming a gate pattern crossing the active region;
forming a spacer insulating layer on sidewalls of the gate pattern;
performing a first silicidation process including forming a partially interrupted first salicide layer on an upper portion of the gate pattern while forming the first salicide layer on the active region between the spacer insulating layer and the device isolation layer; and
performing a second silicidation step including forming a second salicide layer on the upper portion of the gate pattern to electrically connect disconnected portions of the interrupted first salicide layer.

8. The method of claim 7, wherein the first salicide layer is agglomeratedly formed on the upper portion of the gate pattern, and the second salicide layer is formed between interrupted portions of the first salicide layer.

9. The method of claim 7, wherein a silicide annealing is performed at a high temperature ranging from 650° C. to 850° C. in the first salicidation step.

10. The method of claim 7, wherein a silicide annealing is performed at a low temperature ranging from 300° C. to 550° C. in the second salicidation step.

11. The method of claim 7, wherein the first salicidation step comprises:
forming a first metal layer on a surface of a substrate;
forming a capping layer on the first metal layer;
performing a first silicidation annealing with respect to the substrate; and
removing the capping layer and a remaining portion of the first metal layer that was not silicidized.

12. The method of claim 7, wherein the first metal layer is a cobalt layer.

13. The method of claim 7, wherein the second salicidation step comprises:
forming a second metal layer on a surface of a substrate;
forming a capping layer on the second metal layer;
performing a second silicidation annealing with respect to the substrate; and
removing the capping layer and a portion of the second metal layer that was not silicidized.

14. The method of claim 13, wherein the second metal layer is a nickel layer.
